(19) United States
(12) Patent Application Publication
(10) Pub. No.: US 2025/0234715 A1
(43) Pub. Date: Jul. 17, 2025

(54) DISPLAY PANEL AND METHOD FOR PROVIDING THE SAME

(71) Applicant: Samsung Display Co., Ltd., Yongin-si (KR)

(72) Inventors: HYUNEOK SHIN, Yongin-si (KR); JOONYONG PARK, Yongin-si (KR); SUKYOUNG YANG, Yongin-si (KR); DONGMIN LEE, Yongin-si (KR)

(21) Appl. No.: 18/918,222

(22) Filed: Oct. 17, 2024

(30) Foreign Application Priority Data
Jan. 11, 2024 (KR) 10-2024-0005047

(51) Int. Cl. H10K 59/122; H10K 59/12; H10K 59/80; H10K 59/88

(52) U.S. Cl. CPC H10K 59/122; H10K 59/1201; H10K 59/873; H10K 59/88

(57) ABSTRACT

A display panel includes a light-emitting element layer including a pixel defining layer including a light-emitting opening defined therein corresponding to an exposed portion of a first electrode and a side surface which defines the light-emitting opening, a light-emitting pattern and a second electrode within the light-emitting opening, and an encapsulation layer including an inorganic film which covers the second electrode and the side surface of the pixel defining layer within the light-emitting opening and extends to outside the light-emitting opening in a direction away from the light-emitting opening to define an extended portion of the inorganic film, and a filler including hexamethyldisiloxane which is between the pixel defining layer and the extended portion of the inorganic film.

This application claims priority to Korean Patent Application No. 10-2024-0005047 filed on Jan. 11, 2024, and all the benefits accruing therefrom under 35 U.S.C. § 119, the disclosures of which are incorporated by reference herein in their entireties.

### BACKGROUND

### (1) Field

Embodiments of the present disclosure described herein relate to a display panel and a method for providing (or manufacturing) the display panel. More particularly, embodiments of the present disclosure relate to a display panel and a method for providing (or manufacturing) the same that may realize high resolution and have improved reliability.

### (2) Description of the Related Art

A display panel is used in various multimedia devices such as a television, a mobile phone, a tablet computer, a game console, and the like to provide image information to a user. The display panel includes a light-emitting element and a pixel circuit which operates the light-emitting element. The light-emitting elements included in the display panel emit light and create an image based on a voltage applied from the pixel circuit. A patterning scheme of the light-emitting element affects resolution and reliability of a display panel.

### SUMMARY

Embodiments of the present disclosure provide a display panel that implements high resolution and has improved reliability.

Embodiments of the present disclosure provide a method for providing (or manufacturing) a display panel with improved reliability by improving processability.

According to an embodiment, a display panel includes a base layer, a circuit layer disposed on the base layer, a light-emitting element layer disposed on the circuit layer, and an encapsulation layer disposed on the light-emitting element layer, the light-emitting element layer includes a first electrode disposed on the circuit layer, a lower pixel defining layer covering a portion of the first electrode to define a light-emitting opening and disposed on the circuit layer, an upper pixel defining layer defining an upper opening and disposed on the lower pixel defining layer, a light-emitting pattern disposed within the upper opening on the first electrode, and a second electrode disposed on the light-emitting pattern, and the encapsulation layer includes a first encapsulation inorganic film including a first portion disposed within the upper opening and covering the second electrode and a side surface of the upper pixel defining layer, a second portion extending from the first portion in a thickness direction from the light-emitting element layer toward the encapsulation layer, and a third portion extending from the second portion in a direction toward a center of the upper pixel defining layer, and a filler disposed between the upper pixel defining layer and the third portion of the first encapsulation inorganic film and containing hexamethyldisiloxane.

In an implementation, the filler may contain silicon atoms and oxygen atoms, and a ratio of the oxygen atoms to the silicon atoms may be equal to or greater than about 1.5 and equal to or smaller than about 2.5.

In an implementation, the filler may contain silicon atoms and carbon atoms, and a ratio of the carbon atoms to the silicon atoms may be equal to or smaller than about 0.6.

In an implementation, a transmittance in a visible light band of the filler may be equal to or greater than about 95%.

In an implementation, the third portion of the first encapsulation inorganic film may be disposed to be spaced apart from the upper pixel defining layer in the thickness direction.

In an implementation, the filler may be in contact with each of the third portion of the first encapsulation inorganic film and the upper pixel defining layer.

In an implementation, the display panel may further include a dummy filler covering the first portion of the first encapsulation inorganic film, a side surface of the second portion facing the light-emitting pattern, and a top surface of the third portion, and the dummy filler may contain the same material as the filler.

In an implementation, the filler and the dummy filler may be integrally connected to each other.

In an implementation, the display panel may further include a dummy filler disposed to be spaced apart from the upper pixel defining layer with the first portion of the first encapsulation inorganic film interposed between, and the dummy filler may contain the same material as the filler.

In an implementation, the filler and the dummy filler may be spaced apart from each other.

In an implementation, a side surface of the second portion facing the filler may be spaced apart from the filler.

In an implementation, a side surface of the second portion facing the filler may be in contact with the filler.

In an implementation, the upper pixel defining layer may include a first inorganic layer disposed on the lower pixel defining layer, and a second inorganic layer disposed on the first inorganic layer and protruding in a direction toward a center of the light-emitting pattern further than the first inorganic layer.

In an implementation, the display panel may further include an encapsulation organic film disposed on the first encapsulation inorganic film to cover a step caused by the light-emitting element layer, and a second encapsulation inorganic film disposed on the encapsulation organic film.

According to an embodiment, a method for manufacturing (or providing) a display panel includes providing a preliminary display panel including a first electrode, a lower pixel defining layer covering a portion of the first electrode to define a light-emitting opening, an upper pixel defining layer defining an upper opening and disposed on the lower pixel defining layer, a light-emitting pattern disposed within the upper opening on the first electrode, a second electrode disposed on the light-emitting pattern, and a first encapsulation inorganic film disposed on the second electrode, and forming a filler layer by depositing hexamethyldisiloxane on the first encapsulation inorganic film, and the first encapsulation inorganic film includes a first portion disposed within the upper opening and covering the second electrode and a side surface of the upper pixel defining layer, a second portion extending from the first portion in a direction from the first electrode toward the second electrode, and a third portion extending from the second portion in a direction away from a center of the light-emitting pattern.

In an implementation, the filler layer may be formed on an entirety of the preliminary display panel while sealing a space between the upper pixel defining layer and the third portion.

In an implementation, the method may further include etching the filler layer in a direction from the second electrode toward the first electrode in an anisotropic manner. In an implementation, the hexamethyldisiloxane may contain silicon atoms and

oxygen atoms, and a ratio of the oxygen atoms to the silicon atoms may be equal to or greater than about 1.5 and equal to or smaller than about 2.5.

In an implementation, the hexamethyldisiloxane may contain silicon atoms and carbon atoms, and a ratio of carbon atoms to silicon atoms may be equal to or smaller than about 0.6.

In an implementation, the forming of the filler layer may include depositing the hexamethyldisiloxane via a chemical vapor deposition process.

### BRIEF DESCRIPTION OF THE FIGURES

The above and other objects and features of the present disclosure will become apparent by describing in detail embodiments thereof with reference to the accompanying drawings.

FIG. 1 is a perspective view of an assembled display device according to an

embodiment of the present disclosure.

FIG. 2 is an exploded perspective view of a display device according to an embodiment of the present disclosure.

FIG. 3 is a cross-sectional view of a display module according to an embodiment of the present disclosure.

FIG. 4 is a plan view of a display panel according to an embodiment of the present disclosure.

FIG. 5 is an enlarged plan view of a portion of an active area according to an embodiment of the present disclosure.

FIGS. 6A and 6B are cross-sectional views of a display panel according to an embodiment of the present disclosure, respectively, taken along a line I-I′ in FIG. 5.

FIG. 7 is a flowchart of a display panel manufacturing method according to an embodiment of the present disclosure.

FIGS. 8A to 8C are cross-sectional views showing structures of a display panel in a method of providing the display panel according to an embodiment of the present disclosure, respectively.

### DETAILED DESCRIPTION

The present disclosure may make various changes and may have various forms. Thus, specific embodiments will be illustrated in the drawings and will be described in detail in the text. However, this is not intended to limit the present disclosure to a particular form of disclosure, and it should be understood to include all changes, equivalents, or substitutes included in the spirit and scope of the present disclosure.

As used herein, when a component (or a region, a layer, a portion, and the like) is referred to as related to another component such as being “on”, “connected to”, or “coupled to” another component, it means that the component may be directly disposed/connected/coupled on another component or a third component may be disposed between the component and another component.

As used herein, a component (or a region, a layer, a portion, and the like) which is referred to as related to another component such as being “directly disposed” may mean that there is no layer, film, area, plate, and the like added between a portion, such as a layer, a film, an area, a plate, and the like, and another portion. For example, “directly disposed” may mean disposed without using an additional member, such as an adhesive member, between two layers or two members.

Like reference numerals refer to like components. In addition, in the drawings, thicknesses, ratios, and dimensions of components are exaggerated for effective description of technical content. For example, within the Figures and the text of the disclosure, a reference number indicating a singular form of an element may also be used to reference a plurality of the singular element.

The singular expression includes the plural expression unless the context clearly dictates otherwise. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes all of one or more combinations that the associated components may define.

Terms such as first, second, and the like may be used to describe various components, but the components should not be limited by the terms. The above terms are used only for the purpose of distinguishing one component from another. For example, without departing from the scope of the present disclosure, a first component may be named as a second component, and similarly, the second component may also be named as the first component.

In addition, terms such as “beneath”, “below”, “on”, “above” are used to describe the relationship of the components illustrated in the drawings. The above terms are relative concepts, and are described with reference to directions indicated in the drawings. As used herein, “disposed on” may refer to being disposed not only on top of but also beneath a member.

It should be understood that terms such as “comprise,” “include” or “have” are intended to specify that a feature, a number, a step, an operation, a component, a part, or a combination thereof described herein is present, and do not preclude a possibility of addition or existence of one or more other features or numbers, steps, operations, components, parts, or combinations thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to the drawings.

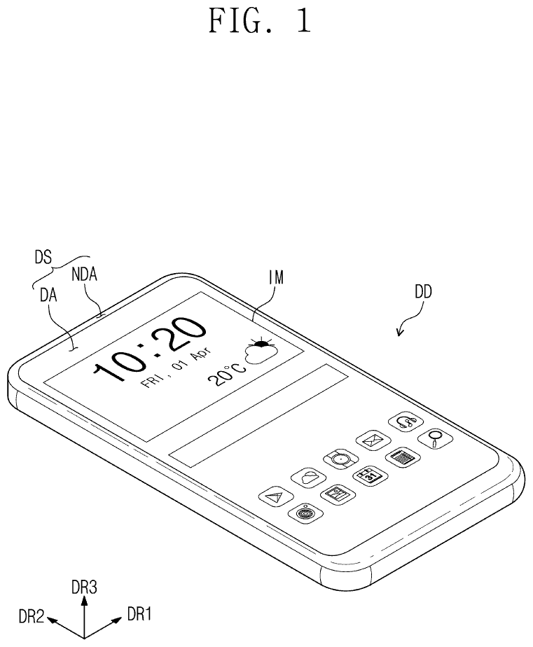

FIG. 1 is a combined perspective view of a display device DD according to an embodiment of the present disclosure.

In an embodiment, the display device DD may be a device such as an electronic device which is activated in response to an electrical signal. For example, the display device DD may be a large electronic device such as a television, a monitor, or an outdoor billboard. Further, the display device DD may be a small and medium-sized electronic device such as a personal computer, a laptop computer, a personal digital terminal, a vehicle navigation unit, a game console, a portable electronic device, and a camera. These are merely examples and the embodiment is not limited thereto. FIG. 1 shows that the display device DD is a mobile phone as an example.

In FIG. 1 and the following drawings, a first direction DR1, a second direction DR2, and a third direction DR3 are shown. Directions indicated by the first to third directions DR1, DR2, and DR3 are relative concept and are able to be converted to other directions. Additionally, directions opposite to the directions indicated by the first to third directions DR1, DR2, and DR3 may also be described as the first to third directions, and the same reference numerals may be used.

Referring to FIG. 1, the display device DD of one embodiment may include a display surface DS defined by the first direction DR1 and the second direction DR2 which intersects the first direction DR1. The display surface DS may be in a plane which is parallel to a pane defined by the first direction DR1 crossing the second direction DR2. The display device DD may provide an image IM to a user via the display surface DS. That is, the image IM may be provided to outside the display device DD via the display surface DS. The display device DD of one embodiment may display the image IM in the third direction DR3 on the display surface DS parallel to each of the first direction DR1 and the second direction DR2. Herein, a front surface (or a top surface) and a rear surface (or a bottom surface) of each component are defined based on the direction in which the image IM is displayed. The front surface and the rear surface may be opposed to each other in the third direction DR3, and a normal direction of each of the front surface and the rear surface may be parallel to the third direction DR3. A thickness of the display device DD and various components or layers thereof may be defined along the third direction DR3 (e.g., a thickness direction).

In one embodiment, the display surface DS may include a display area DA and a non-display area NDA which is adjacent to the display area DA. The non-display area NDA may be an area (e.g., a planar area) where the image IM is not displayed. However, the embodiment may not be limited thereto, and the non-display area NDA may be omitted.

The display device DD according to one embodiment may sense an external input applied from outside (e.g., outside of the display device DD). The external input may include various types of input provided from outside the display device DD. For example, the external input may include a contact by a body part of a user, such as a hand of the user, as well as an external input (e.g., hovering) applied in the vicinity of or at a predetermined distance from the display device DD. Additionally, the external input may have various forms such as a force, a pressure, a temperature, and light.

The display device DD of one embodiment may further include various electronic modules which provide a function to the display device DD (e.g., a functional component). For example, the electronic module may include at least one of a camera, a speaker, a light sensor, and a heat sensor. The electronic module may sense an external subject received via the display surface DS or provide a sound signal such as a voice to the outside via the display surface DS. The electronic module may include a plurality of components and the present disclosure may not be limited to any one embodiment.

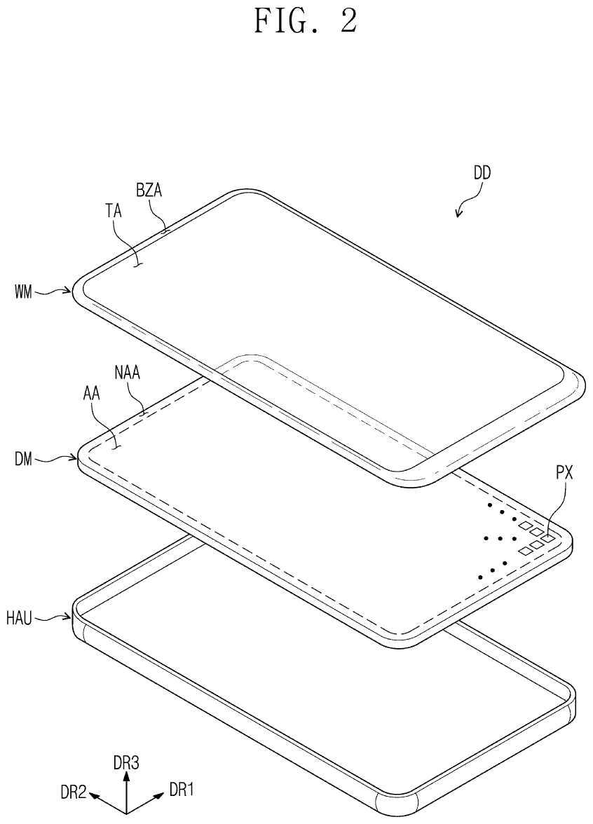

FIG. 2 is an exploded perspective view of the display device DD according to an embodiment of the present disclosure. FIG. 2 shows an exploded perspective view of the display device DD according to an embodiment of the present disclosure in FIG. 1 as an example.

Referring to FIG. 2, the display device DD of one embodiment may include a display module DM and a window WM which is disposed on the display module DM. The display module DM may face the window WM along a thickness direction of the display device DD. The window WM may be disposed on at least one of a top surface and a bottom surface of the display module DM. In FIG. 2, the window WM is shown as disposed on the top surface of the display module DM. The window WM may define an outer surface of the display device DD, without being limited thereto.

In addition, the display device DD of one embodiment may further include the electronic module (not shown) disposed under the display module DM. For example, the electronic module (not shown) may include a camera module.

In addition, although not shown, the display device DD of one embodiment may further include an adhesive layer and/or a polarizing film disposed between the display module DM and the window WM, such as along the thickness direction. Such adhesive layer may couple facing elements to each other. In addition, although not shown, the display device DD of one embodiment may further include a lower functional layer disposed beneath the display module DM.

The display device DD of one embodiment may further include a housing HAU which receives or stores the display module DM, the lower functional layer, and the like. The housing HAU may be coupled with the window WM to constitute an outer appearance (or outer surface) of the display device DD. The housing HAU may include a material with relatively high rigidity. For example, the housing HAU may include a plurality of frames and/or plates made of (or including) glass, plastic, or metal, each of which being relatively rigid. The display module DM may be accommodated in an accommodation space and protected from an external impact. The accommodation space may be defined between and/or by portions of the housing HAU and the window WM.

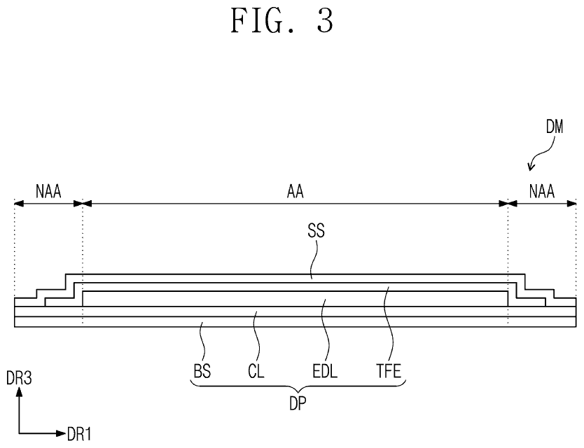

The display module DM of one embodiment may display the image IM (sec FIG. 1) in response to the electrical signal and transmit/receive information on the external input. The display module DM may include a display panel DP (see FIG. 3) and a sensor layer SS (see FIG. 3) which is disposed on the display panel DP (see FIG. 3).

The display module DM may include an active area AA and a peripheral area NAA. The active area AA may be an area in which the image IM (see FIG. 1) is provided. A pixel PX may be disposed in the active area AA. The peripheral area NAA may be adjacent to the active area AA. The peripheral area NAA may surround the active area AA. A driving circuit, a driving wiring, or the like for operating the active area AA may be disposed in the peripheral area NAA.

The display module DM may include a plurality of pixels PX. Each of the pixels PX may emit light in response to the electrical signal. Light emitted by the pixels PX may implement the image IM (see FIG. 1). Each of the pixels PX may include a display element. For example, the display element may be an organic light-emitting element, an inorganic light-emitting element, an organic-inorganic light-emitting element, a micro LED, a nano LED, a quantum dot light-emitting element, an electrophoresis element, an electrowetting element, and the like.

The window WM may cover an entirety of the top surface of the display module DM. The window WM may have a shape (e.g., a planar shape) corresponding to a shape of the display module DM. The window WM may have flexibility to be deformed depending on folding or bending of the display device DD. The window WM may function to protect the display module DM from the external impact. That is, the display device DD may be flexible, bendable, rollable, foldable, etc. Various components or layers within the display device DD may be flexible, bendable, rollable, foldable, etc. together with each other. The window WM may include a transmissive area TA and a bezel area BZA.

The transmissive area TA may overlap at least a portion of the active area AA of the display module DM. The transmissive area TA may be an optically transparent area. For example, the transmissive area TA may have a transmittance of about 90% or greater for wavelengths in a visible light band. The image IM (see FIG. 1) may be provided to outside of the display device DD, such as to the user, via the transmissive area TA and the user may receive information via the image IM (see FIG. 1).

The bezel area BZA may be an area with relatively low light transmittance compared to the light transmittance of the transmissive area TA. The bezel area BZA may define a planar shape of the transmissive area TA. A boundary may be defined between the bezel area BZA and the transmissive area TA. The bezel area BZA may have a predetermined color. The bezel area BZA may cover the peripheral area NAA of the display module DM and may block the peripheral area NAA from being viewed from the outside. This is merely an example and the bezel area BZA may be omitted in the window WM according to one embodiment.

FIG. 3 is a cross-sectional view of the display module DM according to an embodiment of the present disclosure.

Referring to FIG. 3, the display module DM may include the display panel DP and the sensor layer SS which is disposed on the display panel DP. The active area AA and the peripheral area NAA shown in FIG. 3 may correspond to the active area AA and the peripheral area NAA shown in FIG. 2, respectively.

The display panel DP may include a base layer BS, a circuit layer CL, a light-emitting element layer EDL, and an encapsulation layer TFE.

The base layer BS may be a member which provides a base surface on which the circuit layer CL is disposed. The base layer BS may be a rigid substrate or a flexible substrate which may be bent, folded, or rolled. The base layer BS may be a glass substrate, a metal substrate, a polymer substrate, or the like. However, the embodiment of the present disclosure may not be limited thereto and the base layer BS may be an inorganic layer, an organic layer, or a composite material layer.

The circuit layer CL may be disposed on the base layer BS. The circuit layer CL may include an insulating layer, a semiconductor pattern, a conductive pattern, a signal line, and the like. The insulating layer, a semiconductor layer, and a conductive layer may be formed on (or provided on) the base layer BS via coating, deposition, or the like, and then the insulating layer, the semiconductor layer, and the conductive layer may be selectively patterned via a plurality of photolithography processes and etching processes. Thereafter, the semiconductor pattern, the conductive pattern, and the signal line included in the circuit layer CL may be formed.

The light-emitting element layer EDL may be disposed on the circuit layer CL. The light-emitting element layer EDL may include the light-emitting element ED. For example, the light-emitting element ED may include an organic light-emitting material, an inorganic light-emitting material, an organic-inorganic light-emitting material, a quantum dot, a quantum rod, a micro light-emitting diode (LED), or a nano LED. The light-emitting element layer EDL may be connected (i.e., electrically, mechanically, etc.) to the circuit layer CL.

The encapsulation layer TFE may be disposed on the light-emitting element layer EDL. The encapsulation layer TFE may cover the light-emitting element layer EDL. The encapsulation layer TFE may protect the light-emitting element layer EDL from foreign substances such as moisture, oxygen, and dust particles.

The sensor layer SS as a sensing layer may be disposed on the display panel DP. The sensor layer SS may sense the external input applied from outside. The external input may be an input of the user. The input of the user may include various forms of external input, such as the body part of the user, light, heat, a pen, or the pressure. For example, the sensor layer SS may sense the external input in a capacitive manner. In the present disclosure, an operating scheme of the sensor layer SS may not be particularly limited, and the sensor layer SS may sense the external input in an electromagnetic induction scheme or a pressure sensing scheme.

In an embodiment, the sensor layer SS may be formed on the display panel DP via consecutive processes in a method of providing the display device DD. In this case, the sensor layer SS may be disposed directly on the display panel DP. Herein, “directly disposed” may mean that a third component is not disposed between the sensor layer SS and the display panel DP. That is, a separate adhesive member may not be disposed between the sensor layer SS and the display panel DP. For example, the sensor layer SS may be disposed directly on the encapsulation layer TFE of the display panel DP. Additionally, the sensor layer SS may be bonded with the display panel DP via the adhesive member. The adhesive member may include an existing adhesive or gluing agent. The sensor layer SS may provide the outermost layer of the display module DM, without being limited thereto.

The sensor layer SS may have a multi-layer structure. The sensor layer SS may include a single or multi-layer conductive layer. The sensor layer SS may include a single or multi-layer insulating layer.

An optical layer (not shown) may be further disposed on the sensor layer SS. The optical layer may be disposed directly on the sensor layer SS. In an embodiment, the optical layer may be formed on the sensor layer SS via consecutive processes. The optical layer may reduce reflectance by external light incident from the outside of the display module DM. The optical layer may include a polarizing layer or a color filter layer. The optical layer may provide the outermost layer of the display module DM, without being limited thereto.

In one embodiment, the sensor layer SS may be omitted, and the optical layer may be disposed directly on the display panel DP. In one embodiment, the locations of the sensor layer SS and the optical layer may be interchanged.

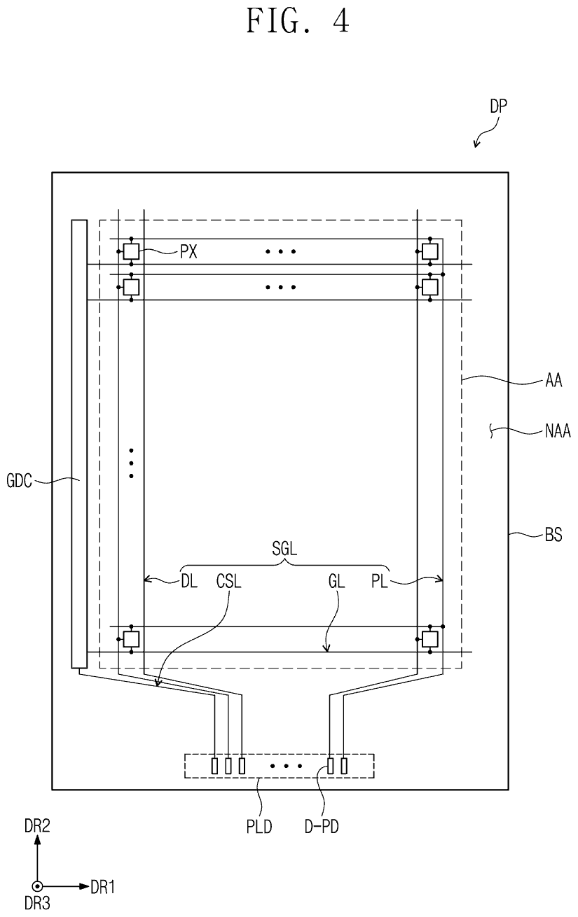

FIG. 4 is a plan view of the display panel DP according to an embodiment of the present disclosure.

Referring to FIG. 4, the display panel DP may include the base layer BS divided into the active area AA and the peripheral area NAA. The base layer BS may define an overall planar shape or overall planar dimension of the display panel DP.

The display panel DP may include the pixels PX disposed in the active area AA and signal lines SGL which are electrically connected to the pixels PX. The display panel DP may include a driving circuit GDC and a pad PLD (e.g., pad area) disposed in the peripheral area NAA.

The pixels PX may be arranged in the first direction DR1 and the second direction DR2. The pixels PX may include a plurality of pixel rows extending in the first direction DR1 and arranged in the second direction DR2, and a plurality of pixel columns extending in the second direction DR2 and arranged in the first direction DR1.

The signal lines SGL may include gate lines GL, data lines DL, a power line PL, and a control signal line CSL. Each of the gate lines GL may be connected to a corresponding pixel among the pixels PX, and each of the data lines DL may be connected to a corresponding pixel among the pixels PX. The power line PL may be electrically connected to the pixels PX. The control signal line CSL may be connected to the driving circuit GDC to provide control signals to the driving circuit GDC.

The driving circuit GDC may include a gate driving circuit. The gate driving circuit may generate gate signals and sequentially output the generated gate signals to the gate lines GL. The gate driving circuit may further output another control signal to the pixel driving circuit.

The pad PLD may be a portion of the display panel DP at which an external component such as a flexible circuit board is connected to the display panel DP. The pad PLD may include pixel pads D-PD, and the pixel pads D-PD may be pads or terminals at which the flexible circuit board is connected to to the display panel DP. Each of the pixel pads D-PD may be connected to a corresponding signal line among the signal lines SGL. The pixel pads D-PD may be connected to the corresponding pixels PX via the signal lines SGL, respectively. Additionally, one of the pixel pads D-PD may be connected to the driving circuit GDC.

Additionally, the pad PLD may further include input pads. The input pads may be pads or terminals at which the flexible circuit board is connected to the sensor layer SS (see FIG. 3). However, the present disclosure may not be limited thereto, and the input pads may be disposed on the sensor layer SS (see FIG. 3) and connected to a circuit board separated from the pixel pads D-PD. Alternatively, the sensor layer SS (see FIG. 3) may be omitted and the input pads may not be further included.

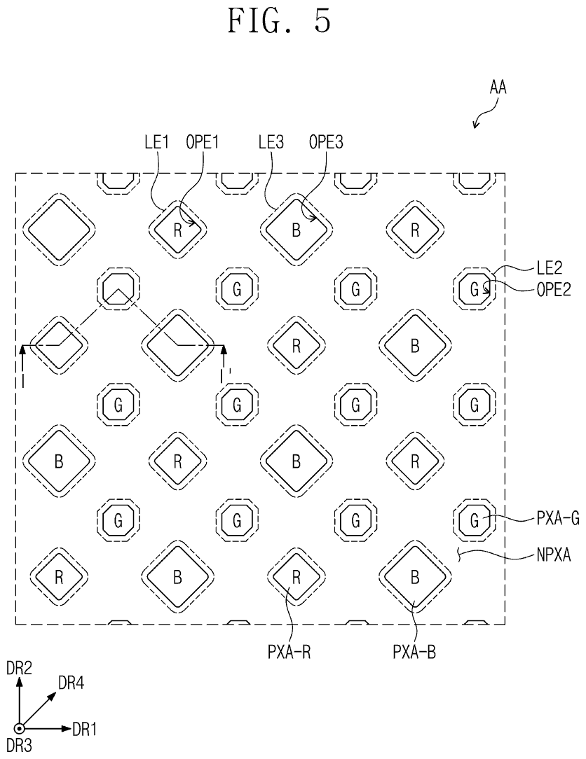

FIG. 5 is an enlarged plan view of a portion of the active area AA according to an embodiment of the present disclosure. FIG. 5 is an enlarged plan view of the active area AA of the display module DM (see FIG. 2) viewed from above the display surface DS (see FIG. 1) as an example.

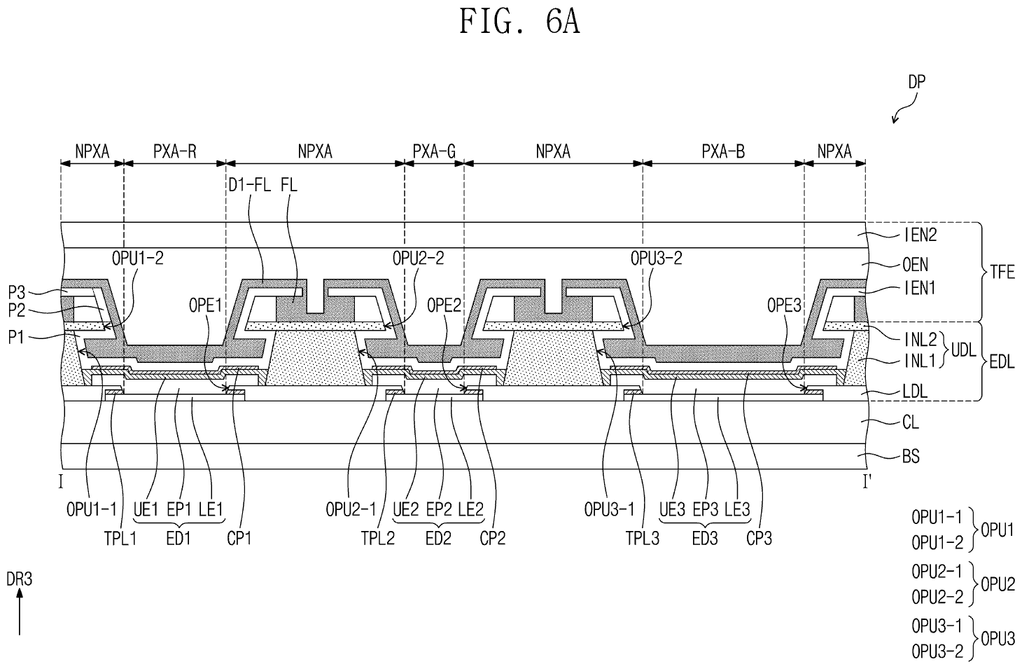

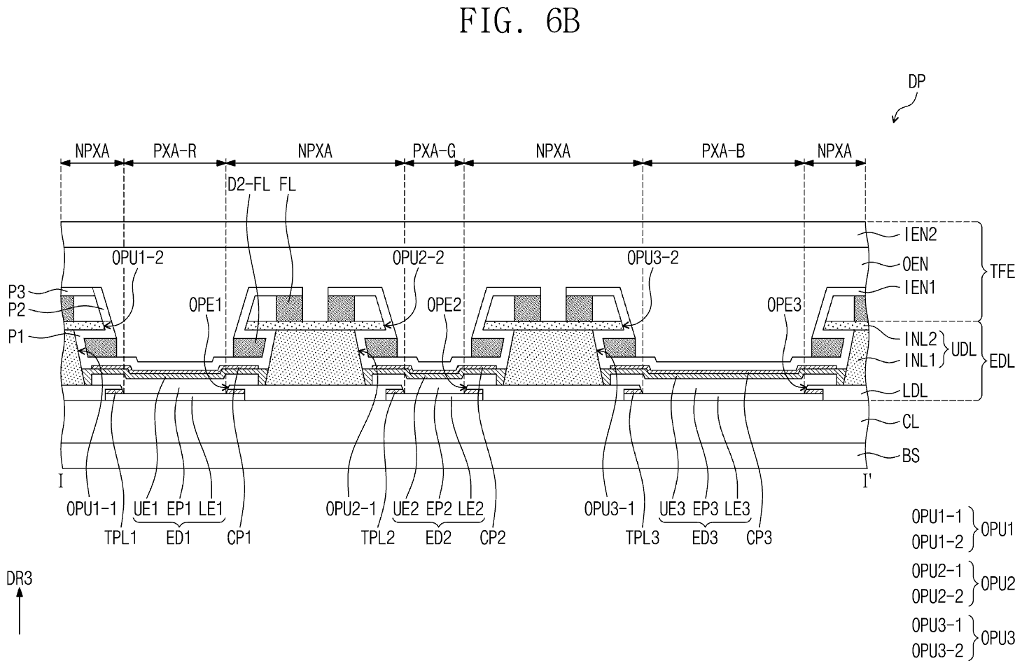

Referring to FIG. 5, the active area AA may include a light-emitting area provided in plural including first to third light-emitting areas PXA-R, PXA-G, and PXA-B, and a non-light-emitting area NPXA which is adjacent to the first to third light-emitting areas PXA-R, PXA-G, and PXA-B. the non-light-emitting area NPXA surrounds the first to third light-emitting areas PXA-R, PXA-G, and PXA-B in a plan view. The first to third light-emitting areas PXA-R, PXA-G, and PXA-B may correspond to areas (e.g., planar areas) where light provided from light-emitting elements ED1, ED2, and ED3 (see FIG. 6A) is emitted, respectively.

In FIG. 5, for convenience of description, only lower electrodes LE1, LE2, and LE3 among components of the light-emitting elements ED1, ED2, and ED3 (see FIG. 6A) are shown as an example. The first to third light-emitting areas PXA-R, PXA-G, and PXA-B may be distinguished from each other based on colors of light emitted toward the outside of the display module DM (see FIG. 2).

The first to third light-emitting areas PXA-R, PXA-G, and PXA-B may provide light of first to third colors having different colors. For example, light of the first color may be red light, light of the second color may be green light, and light of the third color may be blue light. However, examples of light of the first to third colors are not necessarily limited to the above examples.

Among a light-emitting area which is provided in plural, the first to third light-emitting areas PXA-R, PXA-G, and PXA-B may be defined as areas (e.g., planar areas) of the lower electrodes LE1, LE2, and LE3 which are exposed by light-emitting openings OPE1, OPE2, and OPE3 corresponding thereto, respectively. The light-emitting openings OPE1, OPE2, and OPE3 may be defined by (or in) a lower pixel defining layer LDL (see FIG. 6A) which covers portions of the lower electrodes LE1, LE2, and LE3, and a detailed description thereof will be provided later. Here, top surfaces of the lower electrodes LE1, LE2, and LE3 are exposed to outside the lower pixel defining layer LDL by light-emitting openings OPE1, OPE2, and OPE3 which are defined therein.

Specifically, the first light-emitting area PXA-R may be defined as the area of the top surface of the first lower electrode LE1 which is exposed by the first light-emitting opening OPE1. Additionally, the second light-emitting area PXA-G may be defined as the area of the top surface of the second lower electrode LE2 which is exposed by the second light-emitting opening OPE2. Additionally, the third light-emitting area PXA-B may be defined as the area of the top surface of the third lower electrode LE3 which is exposed by the third light-emitting opening OPE3.

The non-light-emitting area NPXA may set boundaries of the first to third light-emitting areas PXA-R, PXA-G, and PXA-B and may prevent color mixing between the first to third light-emitting areas PXA-R, PXA-G, and PXA-B.

The first to third light-emitting areas PXA-R, PXA-G, and PXA-B may be respectively provided in plural to include a plurality of first light-emitting areas, a plurality of second light-emitting areas, and a plurality of third light-emitting areas repeatedly arranged in a predetermined arrangement within the active area AA, respectively.

For example, referring to FIG. 5, each of the plurality of first light-emitting areas PXA-R and each of the plurality of third light-emitting areas PXA-B may be arranged alternately along the first direction DR1 to form a ‘first group’ or a first row of light-emitting areas. Additionally, each of the second light-emitting areas PXA-G may be arranged along the first direction DR1 to form a ‘second group’ or a second row of light-emitting areas. The ‘first group’ and the ‘second group’ may be respectively provided in plural to include a plurality of first groups and a plurality of second groups, respectively, and the ‘first groups’ and the ‘second groups’ may be arranged alternately with each other along the second direction DR2.

A second light-emitting area PXA-G may be disposed to be spaced apart from a first light-emitting area PXA-R or a third light-emitting area PXA-B in a fourth direction DR4. The fourth direction DR4 may be defined as a direction between the first direction DR1 and the second direction DR2 on a plane defined by the first direction DR1 and the second direction DR2, such as to define an inclined direction.

As shown in FIG. 5, the first to third light-emitting areas PXA-R, PXA-G, and PXA-B may have a PENTILE™ arrangement. However, the arrangement of the first to third light-emitting areas PXA-R, PXA-G, and PXA-B shown in FIG. 5 is merely illustrative. Their arrangement may be various without being limited thereto. For example, the first to third light-emitting areas PXA-R, PXA-G, and PXA-B may have a stripe arrangement, or a Diamond Pixel™ arrangement.

In one example, each of the first to third light-emitting areas PXA-R, PXA-G, and PXA-B may have various shapes on the plane (e.g., planar shapes). For example, each of the first to third light-emitting areas PXA-R, PXA-G, and PXA-B may have a polygonal, circular, or oval planar shape. In FIG. 5, the first light-emitting areas PXA-R and the third light-emitting areas PXA-B having a square (or a diamond) planar shape and the second light-emitting area PXA-G having an octagonal shape on the plane are shown as an example.

The first to third light-emitting areas PXA-R, PXA-G, and PXA-B may have the same shape on the plane or at least some of them may have different shapes. FIG. 5 shows the first light-emitting areas PXA-R and the third light-emitting areas PXA-B having the same shape on the plane, and the second light-emitting area PXA-G having a shape different from that of the first light-emitting areas PXA-R and the third light-emitting areas PXA-B as an example.

At least some of the first to third light-emitting areas PXA-R, PXA-G, and PXA-B may have different area sizes on the plane (e.g., planar areas). Specifically, an area size of the first light-emitting area PXA-R which emits red light may be greater than an area size of the second light-emitting area PXA-G which emits green light and smaller than an area size of the third light-emitting area PXA-B which emits blue light. However, a size relationship between the area sizes of the first to third light-emitting areas PXA-R, PXA-G, and PXA-B depending on the colors of emitted light may not be limited thereto and may vary depending on a design of the display module DM (see FIG. 2). For example, the first to third light-emitting areas PXA-R, PXA-G, and PXA-B may have the same area size on the plane.

In one example, the shapes, the area sizes, and the arrangements on the plane of the first to third light-emitting areas PXA-R, PXA-G, and PXA-B of the display module DM (see FIG. 2) of the present disclosure may be designed in various ways depending on the colors of light or a size and a configuration of the display module DM (see FIG. 2), and may not be limited to the embodiment shown in FIG. 5.

The lower electrodes LE1, LE2, and LE3 may be respectively connected to the driving circuits of the pixels in the circuit layer CL (see FIG. 3) described above via connection contact holes (not shown). The connection contact holes may be disposed to be spaced apart from the light-emitting areas PXA-R, PXA-G, and PXA-B as corresponding to locations of the lower electrodes LE1, LE2, and LE3, respectively. Alternatively, the connection contact holes may be defined to at least partially overlap the light-emitting areas PXA-R, PXA-G, and PXA-B as corresponding to locations of the lower electrodes LE1, LE2, and LE3, respectively.

FIGS. 6A and 6B are cross-sectional views of the display panel DP according to an embodiment of the present disclosure, respectively, taken along a line I-I′ in FIG. 5. That is, FIGS. 6A and 6B may represent cross-sections of the first to third light-emitting areas PXA-R, PXA-G, and PXA-B and the non-light-emitting area NPXA which extends around the first to third light-emitting areas PXA-R, PXA-G, and PXA-B in FIG. 5. The first to third light-emitting areas PXA-R, PXA-G, and PXA-B may correspond to the planar areas where light provided from the light-emitting elements ED1, ED2, and ED3 is emitted, respectively.

Referring to FIGS. 6A and 6B, the display panel DP may include the base layer BS, the circuit layer CL disposed on the base layer BS, the light-emitting element layer EDL disposed on the circuit layer CL, and the encapsulation layer TFE disposed on the light-emitting element layer EDL. The same contents as described above with reference to FIG. 3 may be applied to the base layer BS and the circuit layer CL in FIGS. 6A and 6B. FIGS. 6A and 6B illustrate the light-emitting element layer EDL and the encapsulation layer TFE in detail.

The light-emitting element layer EDL may include the light-emitting elements ED1, ED2, and ED3, protection patterns TPL1, TPL2, and TPL3, the lower pixel defining layer LDL, an upper pixel defining layer UDL, and capping patterns CP1, CP2, and CP3.

The light-emitting elements ED1, ED2, and ED3 may include the first light-emitting element ED1, the second light-emitting element ED2, and the third light-emitting element ED3. The first light-emitting element ED1 may include the first lower electrode LE1, a first light-emitting pattern EP1, and a first upper electrode UE1. The second light-emitting element ED2 may include the second lower electrode LE2, a second light-emitting pattern EP2, and a second upper electrode UE2. The third light-emitting element ED3 may include the third lower electrode LE3, a third light-emitting pattern EP3, and a third upper electrode UE3.

The first to third lower electrodes LE1, LE2, and LE3 may be provided in a plurality of patterns. As being a pattern, an element may be a discrete pattern having a discrete planar shape. Hereinafter, a description will focus on the pattern of the first lower electrode LE1, and the description of the first lower electrode LE1 may be equally applied to the patterns of the second lower electrode LE2 and the third lower electrode LE3.

The first to third lower electrodes LE1, LE2, and LE3 may together provide a lower electrode layer. That is, the first to third lower electrodes LE1, LE2, and LE3 may be in a same layer as each other. As being in a same layer, elements may be formed in a same process and/or include a same material as each other, elements may be respective portions of a same material layer, elements may be ‘on’ a same layer by forming an interface with a same underlying or overlying layer, etc., without being limited thereto.

The first lower electrode LE1 may be disposed on the circuit layer CL. The first lower electrode LE1 may be a (semi-)transmissive electrode or a reflective electrode. The first lower electrode LE1 may have a single layer or multiple layers. For example, the first lower electrode LE1 may include a first layer and a second layer.

The first layer may include a metallic material. For example, the first layer may be a reflective layer made of silver (Ag), magnesium (Mg), aluminum (Al), platinum (Pt), palladium (Pd), gold (Au), nickel (Ni), neodymium (Nd), iridium (Ir), chromium (Cr), or a combination thereof.

The second layer may be disposed on the first layer. The second layer may include a transparent conductive oxide. For example, the second layer may be a transparent or translucent layer including at least one selected from an indium tin oxide (ITO), an indium zinc oxide (IZO), an indium gallium zinc oxide (IGZO), a zinc oxide (ZnO), an indium oxide (In₂O₃), and an aluminum-doped zinc oxide (AZO). In one embodiment, the second layer may include a crystallized transparent conductive oxide, and, for example, the transparent conductive oxide may include poly-ITO.

In one embodiment, the first lower electrode LE1 may further include a third layer under the first layer, such that the third layer, the first layer and the second layer may be in order from the base layer, along the thickness direction. The third layer may include a transparent conductive oxide. In this regard, the third layer may include the same material as the second layer or may include a material different from that of the second layer.

Each of the first to third light-emitting patterns EPI, EP2, and EP3 may be disposed on a respective lower electrode corresponding thereto among the first to third lower electrodes LE1, LE2, and LE3. Specifically, the first light-emitting pattern EP1 may be disposed on the first lower electrode LE1, the second light-emitting pattern EP2 may be disposed on the second lower electrode LE2, and the third light-emitting pattern EP3 may be disposed on the third lower electrode LE3. In one embodiment, the first light-emitting pattern EP1 may provide red light, the second light-emitting pattern EP2 may provide green light, and the third light-emitting pattern EP3 may provide blue light.

Each of the first to third light-emitting patterns EP1, EP2, and EP3 may include a light-emitting layer including a light-emitting material. Each of the first to third light-emitting patterns EP1, EP2, and EP3 may further include a hole injection layer and/or a hole transport layer disposed between the light-emitting layer and the lower electrode corresponding thereto among the first to third lower electrodes LE1, LE2, and LE3. In addition, each of the first to third light-emitting patterns EP1, EP2, and EP3 may further include an electron transport layer and an electron injection layer disposed on the light-emitting layer. The first light-emitting pattern EP1, the second light-emitting pattern EP2, and the third light-emitting pattern EP3 may be patterned by being disposed in lower openings including the first light-emitting opening OPE1, the second light-emitting opening OPE2, and the third light-emitting opening OPE3 defined by the lower pixel defining layer LDL, respectively.

In addition, the first light-emitting pattern EP1, the second light-emitting pattern EP2, and the third light-emitting pattern EP3 may be disposed in a first upper opening OPU1, a second upper opening OPU2, and a third upper opening OPU3 defined by the upper pixel defining layer UDL, respectively. Specifically, the first light-emitting pattern EPI, the second light-emitting pattern EP2, and the third light-emitting pattern EP3 may be disposed in a (1-1)-th upper opening OPU1-1 as a first lower sub-opening, a (2-1)-th upper opening OPU2-1 as a second lower sub-opening, and a (3-1)-th upper opening OPU3-1 as a third lower sub-opening each defined by a first inorganic layer INL1 of the upper pixel defining layer UDL, respectively.

Accordingly, portions of a top surface of the lower pixel defining layer LDL not covered by the first inorganic layer INL1 and exposed outside of the first inorganic layer INL1 to the (1-1)-th upper opening OPU1-1, the (2-1)-th upper opening OPU2-1, and the (3-1)-th upper opening OPU3-1 may be at least partially covered by the first light-emitting pattern EP1, the second light-emitting pattern EP2, and the third light-emitting pattern EP3, respectively.

It is shown in FIGS. 6A and 6B that the portions of the top surface of the lower pixel defining layer LDL exposed to the lower sub-openings as including the (1-1)-th upper opening OPU1-1, the (2-1)-th upper opening OPU2-1, and the (3-1)-th upper opening OPU3-1 are partially covered, but the present disclosure may not be limited thereto and an entirety of the exposed portions of the top surface of the lower pixel defining layer LDL may be covered by the first light-emitting pattern EP1, the second light-emitting pattern EP2, and the third light-emitting pattern EP3.

The first to third upper electrodes UE1, UE2, and UE3 may be respectively disposed on light-emitting patterns corresponding thereto among the first to third light-emitting patterns EP1, EP2, and EP3. Specifically, the first upper electrode UE1 may be disposed on the first light-emitting pattern EP1, the second upper electrode UE2 may be disposed the second light-emitting pattern EP2, and the third upper electrode UE3 may be disposed the third light-emitting pattern EP3. The first to third upper electrodes UE1, UE2, and UE3 may together provide an upper electrode layer and may be in a same layer as each other.

The first upper electrode UE1, the second upper electrode UE2, and the third upper electrode UE3 may be patterned by material being disposed in the first upper opening OPU1, the second upper opening OPU2, and the third upper opening OPU3, respectively, defined by the upper pixel defining layer UDL. Specifically, the first upper electrode UE1, the second upper electrode UE2, and the third upper electrode UE3 may be disposed in the (1-1)-th upper opening OPU1-1 as a first upper sub-opening, the (2-1)-th upper opening OPU2-1 as a second upper sub-opening, and the (3-1)-th upper opening OPU3-1 as a third upper sub-opening defined by the first inorganic layer INL1 of the upper pixel defining layer UDL, respectively.

Accordingly, the portions of the top surface of the lower pixel defining layer LDL not covered by the first inorganic layer INL1 and exposed to the (1-1)-th upper opening OPU1-1, the (2-1)-th upper opening OPU2-1, and the (3-1)-th upper opening OPU3-1 may be at least partially covered.

That is, as shown in FIGS. 6A and 6B, the first upper electrode UE1, the second upper electrode UE2, and the third upper electrode UE3 may cover portions of the top surface of the lower pixel defining layer LDL which are not covered by the first light-emitting pattern EPI, the second light-emitting pattern EP2, and the third light-emitting pattern EP3, of the portions of the top surface of the lower pixel defining layer LDL exposed to the (1-1)-th upper opening OPU1-1, the (2-1)-th upper opening OPU2-1, and the (3-1)-th upper opening OPU3-1, respectively.

The first upper electrode UE1 may be in contact with at least a portion of a side surface of the upper pixel defining layer UDL which defines the first upper opening OPU1. Specifically, the first upper electrode UE1 may be in contact with at least a portion of a side surface of the first inorganic layer INL1 which defines the (1-1)-th upper opening OPU1-1.

Accordingly, the first upper electrode UE1 may be electrically connected to the first inorganic layer INL1 and may receive a bias voltage via the first inorganic layer INL1. The description regarding the first upper electrode UE1 above may be equally applied to the second and third upper electrodes UE2 and UE3.

In one example, when the upper electrode layer is in a form of a common layer which overlaps all of the first to third light-emitting patterns EP1, EP2, and EP3, a lateral leakage current may occur via the common layer. On the other hand, the first to third upper electrodes UE1, UE2, and UE3 as respective patterns in the upper electrode layer according to the present disclosure may be provided spaced apart from each other on the first to third light-emitting patterns EP1, EP1, and EP3 which are spaced apart from each other, thereby preventing the lateral leakage current which may occur when the upper electrode is in the form of the common layer.

In addition, as the upper electrodes UE1, UE2, and UE3 are electrically connected to the first inorganic layer INL1, which has a relatively large thickness, a driving electrical resistance of the first to third light-emitting elements ED1, ED2, and ED3 is reduced, so that a light-emitting efficiency may be increased and a lifespan may be increased.

Within a protection layer, the first protection pattern TPL1 may define a first lower opening which exposes a portion of a top surface of the first lower electrode LE1, the second protection pattern TPL2 may define a second lower opening which exposes a portion of a top surface of the second lower electrode LE2, and the third protection pattern TPL3 may define a third lower opening which exposes a portion of a top surface of the third lower electrode LE3. That is, the first to third protection patterns TPL1, TPL2, and TPL3 may be in a same layer as each other.

The first to third protection patterns TPL1, TPL2, and TPL3 may define the first light-emitting opening OPE1, the second light-emitting opening OPE2, and the third light-emitting opening OPE3 shown in FIGS. 6A and 6B, respectively, together with openings in the lower pixel defining layer LDL.

The lower pixel defining layer LDL and the protection layer may each include sidewalls respectively defining portions of the light-emitting openings. The sidewall of lower pixel defining layer LDL may define a lower thickness portion (or a lower volume) of a respective light-emitting opening, where the sidewall of the protection layer may define an upper thickness portion (or an upper volume) of the respectively light-emitting opening. The lower electrode layer includes exposed portions at each of the light-emitting openings.

In one example, unlike as shown in FIGS. 6A and 6B, the protection patterns TPL1, TPL2, and TPL3 may be omitted. In this case, a sidewall of the lower pixel defining layer LDL may define the first light-emitting opening OPE1, the second light-emitting opening OPE2, and the third light-emitting opening OPE3 on the first lower electrode LE1, the second lower electrode LE2, and the third lower electrode LE3, respectively.

The protection patterns TPL1, TPL2, and TPL3 may prevent the first to third lower electrodes LE1, LE2, and LE3 from being damaged during an etching process in a method to form (or provide) the lower pixel defining layer LDL.

The lower pixel defining layer LDL may be disposed on the circuit layer CL. Additionally, the lower pixel defining layer LDL may be disposed to cover portions of the top surfaces of the first to third lower electrodes LE1, LE2, and LE3, and may define the first to third light-emitting openings OPE1, OPE2, and OPE3.

In addition, when the first to third protection patterns TPL1, TPL2, and TPL3 are respectively disposed on ends of the top surfaces of the first to third lower electrodes LE1, LE2, and LE3, as shown in FIGS. 6A and 6B, the lower pixel defining layer LDL may be extended from a respective non-light-emitting area to be disposed on the top surfaces of the first to third protection patterns TPL1, TPL2, and TPL3. Accordingly, the first to third protection patterns TPL1, TPL2, and TPL3 may define the first to third light-emitting openings OPE1, OPE2, and OPE3, respectively, along with the lower pixel defining layer LDL.

In FIGS. 6A and 6B, respective side surfaces of the first to third protection patterns TPL1, TPL2, and TPL3 which define the first to third light-emitting openings OPE1, OPE2, and OPE3 are shown to be closer to centers of the first to third lower electrodes LE1, LE2, and LE3 than a side surface of the lower pixel defining layer LDL, respectively. However, the present disclosure may not be limited thereto, and the side surface of the lower pixel defining layer LDL may be closer to the centers of the first to third lower electrodes LE1, LE2, and LE3 than the side surfaces of the first to third protection patterns TPL1, TPL2, and TPL3 on the plane. In an embodiment, the side surfaces (e.g., sidewalls) of the lower electrode layer and the lower pixel defining layer LDL may be aligned with each other at a respective pixel opening, such as to be in a line along the thickness direction and/or coplanar with each other in a plane defined by the third direction DR3 and a direction along a plane including the first, second and fourth directions DR1, DR2 and DR4.

The lower pixel defining layer LDL may include an inorganic insulating material, for example, silicon nitride (SiNₓ). The lower pixel defining layer LDL may be disposed between the first to third lower electrodes LE1, LE2, and LE3 and the upper pixel defining layer UDL, respectively, to block electrical connection between the first to third lower electrodes LE1, LE2, and LE3 and the upper pixel defining layer UDL.

The protection patterns TPL1, TPL2, and TPL3 may include the first protection pattern TPL1, the second protection pattern TPL2, and the third protection pattern TPL3. Specifically, the first protection pattern TPL1 may be disposed on the top surface of the first lower electrode LE1, the second protection pattern TPL2 may be disposed on the top surface of the second lower electrode LE2, and the third protection pattern TPL3 may be disposed on the top surface of the third lower electrode LE3.

The upper pixel defining layer UDL may be disposed on the lower pixel defining layer LDL. The first to third upper openings OPU1, OPU2, and OPU3 may be defined by the upper pixel defining layer UDL.

The upper pixel defining layer UDL may include the first inorganic layer INL1 and a second inorganic layer INL2. The first inorganic layer INL1 may be disposed on the lower pixel defining layer LDL, and the second inorganic layer INL2 may be disposed on the first inorganic layer INL1. A thickness of the first inorganic layer INL1 may be greater than a thickness of the second inorganic layer INL2.

On a plane (e.g., in a direction along the circuit layer CL, along the base layer BS, along the display panel DP, etc.), a side surface of the second inorganic layer INL2 may be closer to the centers of the first to third lower electrodes LE1, LE2, and LE3 than the side surface of the first inorganic layer INL1. The side surface of the second inorganic layer INL2 may extend further than the side surface of the first inorganic layer INL1, at a respective upper opening, to define an extended portion of the second inorganic layer INL2. In the second inorganic layer INL2, the extended portions as portions closer to the centers of the first to third lower electrodes LE1, LE2, and LE3 than the side surface of the first inorganic layer INL1 may be defined as tips of the upper pixel defining layer UDL.

The lower sub-openings as including the (1-1)-th upper opening OPU1-1, the (2-1)-th upper opening OPU2-1, and the (3-1)-th upper opening OPU3-1 may be defined by the first inorganic layer INL1. The upper sub-openings as including the (1-2)-th upper opening OPU1-2, a (2-2)-th upper opening OPU2-2, and a (3-2)-th upper opening OPU3-2 may be defined by the second inorganic layer INL2. The (1-2)-th upper opening OPU1-2, the (2-2)-th upper opening OPU2-2, and the (3-2)-th upper opening OPU3-2 may correspond to the first light-emitting opening OPE1, the second light-emitting opening OPE2, and the third light-emitting opening OPE3, respectively.

Solid portions of the lower pixel defining layer LDL, the first inorganic layer INL1 and the second inorganic layer INL2 which respectively overlap each other along the thickness direction may together define a partition or bank of a pixel defining layer LDL and UDL. Light-emitting openings, lower sub-openings and upper sub-openings which respectively overlap each other may together define a pixel opening of the pixel defining layer LDL and UDL

On a plane, area sizes of the (1-1)-th upper opening OPU1-1, the (2-1)-th upper opening OPU2-1, and the (3-1)-th upper opening OPU3-1 may be greater than area sizes of the (1-2)-th upper opening OPU1-2, the (2-2)-th upper opening OPU2-2, and the (3-2)-th upper opening OPU3-2, respectively. Additionally, on the plane, the area sizes of the (1-1)-th upper opening OPU1-1, the (2-1)-th upper opening OPU2-1, and the (3-1)-th upper opening OPU3-1 may be greater than area sizes of the first light-emitting opening OPE1, the second light-emitting opening OPE2, and the third light-emitting opening OPE3, respectively. Here, the horizontal direction of FIGS. 6A and 6B may represent the respective planar areas (e.g., area sizes) of the various elements.

Each of the first inorganic layer INL1 and the second inorganic layer INL2 may include an inorganic material. Each of the first inorganic layer INL1 and the second inorganic layer INL2 may include an insulating inorganic layer or a conductive metal. Each of the first inorganic layer INL1 and the second inorganic layer INL2 may include the conductive metal. For example, the first inorganic layer INL1 may include aluminum (Al) or molybdenum (Mo), and the second inorganic layer INL2 may include titanium (Ti). However, the materials included in the first and second inorganic layers INL1 and INL2 may not be limited thereto. For example, the second inorganic layer INL2 may include an insulating material.

In an etching process of a method of providing the display panel DP, to form the upper pixel defining layer UDL, an etch rate of a first inorganic layer material of the first inorganic layer INL1 may be greater than an etch rate of a second inorganic layer material of the second inorganic layer INL2. That is, the first inorganic layer INL1 may include a material with a higher etch selectivity than that of the second inorganic layer INL2.

The second inorganic layer INL2 may include a material with lower reflectance (e.g., light reflectance) than that of the first inorganic layer INL1. Since the second inorganic layer INL2 constitutes an upper portion of the upper pixel defining layer UDL which is closer to a viewing side of the display device DD, the second inorganic layer INL2 may reduce reflectance of external light from outside the display device DD at a top surface of the upper pixel defining layer UDL to improve a display quality of the display panel DP.

In one example, the upper pixel defining layer UDL may further include a third inorganic film (not shown). The third inorganic film may be disposed between the lower pixel defining layer LDL and the first inorganic layer INL1. That is, the third inorganic film, the first inorganic layer INL1 and the second inorganic layer INL2 may be in order from the lower pixel defining layer LDL within the pixel defining layer. The above-described content of the second inorganic layer INL2 may be applied to the third inorganic film.

The capping patterns CP1, CP2, and CP3 may include the first capping pattern CPI disposed on the first upper electrode UE1, the second capping pattern CP2 disposed on the second upper electrode UE2, and the third capping pattern CP3 disposed on the third upper electrode UE3.

Each of the capping patterns CP1, CP2, and CP3 may include a single layer or multiple layers. The capping patterns CP1, CP2, and CP3 may be inorganic or organic layers. For example, when the capping patterns CP1, CP2, and CP3 include inorganic materials, the inorganic materials may include an alkali metal compound such as LiF, an alkaline earth metal compound such as MgF₂, SiON, SiNₓ, SiO_{y}, and the like. For example, when the capping patterns CP1, CP2, and CP3 include organic materials, the organic materials may include α-NPD, NPB, TPD, m-MTDATA, Alq3, CuPc, TPD15 (N4,N4,N4′,N4′-tetra (biphenyl-4-yl)biphenyl-4,4′-diaminc), TCTA (4,4′,4″-Tris(carbazol-9-yl)triphenylamine), and the like, or may include epoxy resin or acrylate such as methacrylate.

The capping patterns CP1, CP2, and CP3 may function as buffer layers which protect the light-emitting elements ED1, ED2, and ED3 and the like disposed below. A refractive index of the capping patterns CP1, CP2, and CP3 may be equal to or greater than about 1.6. For example, the refractive index of the capping patterns CP1, CP2, and CP3 may be approximately 1.9. The capping patterns CP1, CP2, and CP3 may have the refractive index of about 1.9, thereby improving a light extraction efficiency or the like of the light-emitting element layer EDL. The capping patterns CP1, CP2, and CP3 may be omitted.

The encapsulation layer TFE may cover the light-emitting elements ED1, ED2, and ED3. The encapsulation layer TFE may seal the light-emitting element layer EDL. The encapsulation layer TFE may be a thin film encapsulation layer. The encapsulation layer TFE may be of a single layer (e.g., a monolayer) or a stack of a plurality of layers. The encapsulation layer TFE may include at least one insulating layer.

The encapsulation layer TFE may include at least one inorganic film and at least one organic film. The encapsulation layer TFE may include a first encapsulation inorganic film IEN1, an encapsulation organic film OEN, and a second encapsulation inorganic film IEN2.

The first encapsulation inorganic film IEN1 and the second encapsulation inorganic film IEN2 protect the light-emitting element layer EDL from moisture and oxygen.

The first encapsulation inorganic film IEN1 and the second encapsulation inorganic film IEN2 may include silicon nitride, silicon oxy nitride, silicon oxide, titanium oxide, aluminum oxide, or the like, but may not be particularly limited thereto.

The encapsulation organic film OEN protects the light-emitting element layer EDL from the foreign substances such as the dust particles. The encapsulation organic film OEN may include an acrylic compound, an epoxy-based compound, and the like. The encapsulation organic film OEN may include a photopolymerizable organic material and may not be particularly limited. Additionally, the encapsulation organic film OEN may cover and flatten a step caused by the light-emitting element layer EDL disposed below. The encapsulation organic film OEN may planarize a stepped structure underneath and provide a flat top surface. That is, the encapsulation organic film OEN which is on the first encapsulation inorganic film IEN1 planarizes the first encapsulation inorganic film IEN1.

The first encapsulation inorganic film IEN1 may be disposed to cover the light-emitting element layer EDL. The first encapsulation inorganic film IEN1 may be disposed on the upper electrodes UE1, UE2, and UE3. When the capping patterns CP1, CP2, and CP3 are respectively disposed on the upper electrodes UE1, UE2, and UE3 as shown in FIGS. 6A and 6B, the first encapsulation inorganic film IEN1 may be disposed on the capping patterns CP1, CP2, and CP3. The first encapsulation inorganic film IEN1 may cover exposed portions of top surfaces of the upper electrodes UE1, UE2, and UE3 and exposed portions of top surfaces of the capping patterns CP1, CP2, and CP3 exposed within the pixel openings.

The first encapsulation inorganic film IEN1 may extend from the non-light-emitting area NPXA (e.g., from the partition or bank of the pixel defining layer) to cover exposed portions of the side surfaces of the first inorganic layer INL1 within the pixel openings. That is, the first encapsulation inorganic film IEN1 may cover various side surfaces of layers which define the (1-1)-th to (3-1)-th upper openings OPU1-1, OPU2-1, and OPU3-1. The first encapsulation inorganic film IEN1 may cover an exposed portion of a bottom surface of the second inorganic layer INL2 at the tips thereof. Specifically, the second inorganic layer INL2 further protrudes in directions toward centers of the light-emitting patterns EP1, EP2, and EP3 compared to the first inorganic layer INL1, and accordingly, the portion of the bottom surface of the second inorganic layer INL2 which is defined by the tips is exposed without being in contact with the first inorganic layer INL1. The exposed portion of the bottom surface of the second inorganic layer INL2 which is at the tips thereof may be covered by the first encapsulation inorganic film IEN1. The first encapsulation inorganic film IEN1 may cover the side surface of the second inorganic layer INL2. That is, the first encapsulation inorganic film IEN1 may cover the various side surfaces of layers which define the (1-2)-th to (3-2)-th upper openings OPU1-2, OPU2-2, and OPU3-2.

The first encapsulation inorganic film IEN1 may be virtually divided to include a first portion P1, a second portion P2, and a third portion P3. The first portion P1 may be disposed within the first upper opening OPU1, the second upper opening OPU2, and the third upper opening OPU3 defined by the upper pixel defining layer UDL. The first portion PI may include material of the first encapsulation inorganic film IEN1 within the pixel opening from the respective light-emitting element up to a sidewall of the second inorganic layer INL2, inclusive. The second portion P2 may be disposed to extend from an end (e.g., a distal end) of the first portion PI and in the third direction DR3. However, the present disclosure is not limited to the case of extending exactly in the third direction DR3. For example, it is shown in FIGS. 6A and 6B that the second portion P2 extends at a predetermined angle from the third direction DR3. The third portion P3 may be disposed to extend from an end (e.g., a distal end) of the second portion P2 in a direction toward a center of the upper pixel defining layer UDL (e.g., a center of the partition or bank) on a plane.

As shown in FIGS. 6A and 6B, the third portion P3 of the first encapsulation inorganic film IEN1 may be disposed to be spaced apart from the second inorganic layer INL2 in the third direction DR3. A gap or space may be defined between the third portion P3 of the first encapsulation inorganic film IEN1 and the second inorganic layer INL2.

The encapsulation layer TFE may further include a filler FL. The filler FL may be disposed between the first encapsulation inorganic film IEN1 and the upper pixel defining layer UDL. Specifically, the filler FL may be disposed between the third portion P3 of the first encapsulation inorganic film IEN1 and the second inorganic layer INL2 of the upper pixel defining layer UDL which are spaced apart from each other. The filler FL may occupy a portion (e.g., a volume) of the gap defined between the third portion P3 of the first encapsulation inorganic film IEN1 and an upper surface of the second inorganic layer INL2. The filler FL may be in contact with each of the third portion P3 of the first encapsulation inorganic film IEN1 and the upper pixel defining layer UDL. As being in contact, elements may form an interface therebetween.

The filler FL may fill an entirety or only a portion of the space between the third portion P3 of the first encapsulation inorganic film IEN1 and the second inorganic layer INL2 of the upper pixel defining layer UDL. When the filler FL fills only the portion of the space between the third portion P3 of the first encapsulation inorganic film IEN1 and the second inorganic layer INL2 of the upper pixel defining layer UDL, the filler FL may be disposed to be spaced apart from the second portion P2 of the first encapsulation inorganic film IEN1. That is, a remaining portion of the gap may correspond to the tips of the second inorganic layer INL2. When the filler FL fills the entirety of the space between the third portion P3 of the first encapsulation inorganic film IEN1 and the second inorganic layer INL2 of the upper pixel defining layer UDL, the filler FL may be disposed to be in contact with the second portion P2 of the first encapsulation inorganic film IEN1 in addition to the third portion P3 thereof and the second inorganic layer INL2.

The filler FL may be disposed to seal an inlet of the space between the upper pixel defining layer UDL and the third portion P3 of the first encapsulation inorganic film IEN1. Such inlet may be defined at ends of the first encapsulation inorganic film IEN1 which face each other at the partition or bank. The space between the upper pixel defining layer UDL and the third portion P3 of the first encapsulation inorganic film IEN1 may be completely filled or only partially filled, but in both cases, the space may be sealed by the filler FL. Where the gap between the upper pixel defining layer UDL and the third portion P3 of the first encapsulation inorganic film IEN1 is completely filled, a side surface of the second portion P2 of the first encapsulation inorganic film IEN1 faces the filler FL and contacts the filler FL in a lateral direction along the light-emitting element layer EDL.

As the space between the upper pixel defining layer UDL and the third portion P3 of the first encapsulation inorganic film IEN1 is sealed, in a process for forming one type of pixel area and then forming another type of pixel area, moisture penetration and/or physicochemical damage to exposed material via the space between the upper pixel defining layer UDL and the third portion P3 of the first encapsulation inorganic film IEN1 may be prevented. For example, within a method of providing the display panel DP, in a process for forming the first light-emitting area PXA-R and then forming the second light-emitting area PXA-G after the forming of the first light-emitting area PXA-R, the moisture penetration and/or the physicochemical damage to material via the space between the upper pixel defining layer UDL and the third portion P3 of the first encapsulation inorganic film IEN1 may be prevented.

The filler FL may include hexamethyldisiloxane. Hexamethyldisiloxane may have a SiOₓC_{y} composition. Hexamethyldisiloxane may have excellent reflow properties. Additionally, hexamethyldisiloxane may have properties which prevent penetration of moisture and oxygen.

The filler FL may include silicon (Si) atoms, oxygen (O) atoms, and carbon (C) atoms. A ratio of oxygen atoms to silicon atoms may be equal to or greater than about 1.5 and equal to or smaller than about 2.5. A ratio of carbon atoms to silicon atoms may be equal to or smaller than about 0.6. In the above range, hexamethyldisiloxane included in the filler FL may have properties similar to those of silicon oxide (SiO₂) and therefore may have transparent properties. For example, a transmittance in the visible light band of the filler FL may be about 95% or greater.

The encapsulation layer TFE may further include dummy fillers D1-FL and D2-FL. The dummy fillers D1-FL and D2-FL may be a term defined to refer to things which include the same material as and are formed via the same process as the filler FL, but are different from the filler FL only in locations.

Referring to FIG. 6A, the dummy filler D1-FL may continuously extend from the filler FL at the non-light-emitting area NPXA to cover the first portion P1 of the first encapsulation inorganic film IEN1, a side surface of the second portion P2 facing the light-emitting patterns EP1, EP2, and EP3, and a top surface of the third portion P3. The dummy filler D1-FL may be a component integrally connected to the filler FL to form a single, unitary body. Specifically, the dummy filler D1-FL may cover a side surface facing the center of the upper pixel defining layer UDL of the third portion P3 within a respective pixel opening and may continuously extend therefrom to be integrally connected with the filler FL disposed under the third portion P3 at the partition or bank adjacent to the respective pixel opening.

Referring to FIG. 6B, the dummy filler D2-FL may be disposed to be spaced apart from the upper pixel defining layer UDL with the first portion PI of the first encapsulation inorganic film IEN1 interposed therebetween. Here, a filler layer may include the dummy fillers D1-FL and D2-FL as discrete patterns of a filler material.

The dummy fillers D1-FL and D2-FL may include the same material as the filler FL. The dummy fillers D1-FL and D2-FL may be formed in the same process step as the filler FL. The dummy fillers D1-FL and D2-FL may have transparent properties.

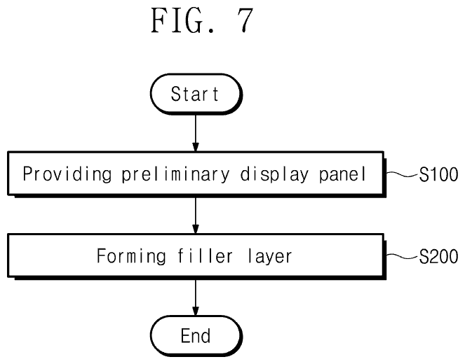

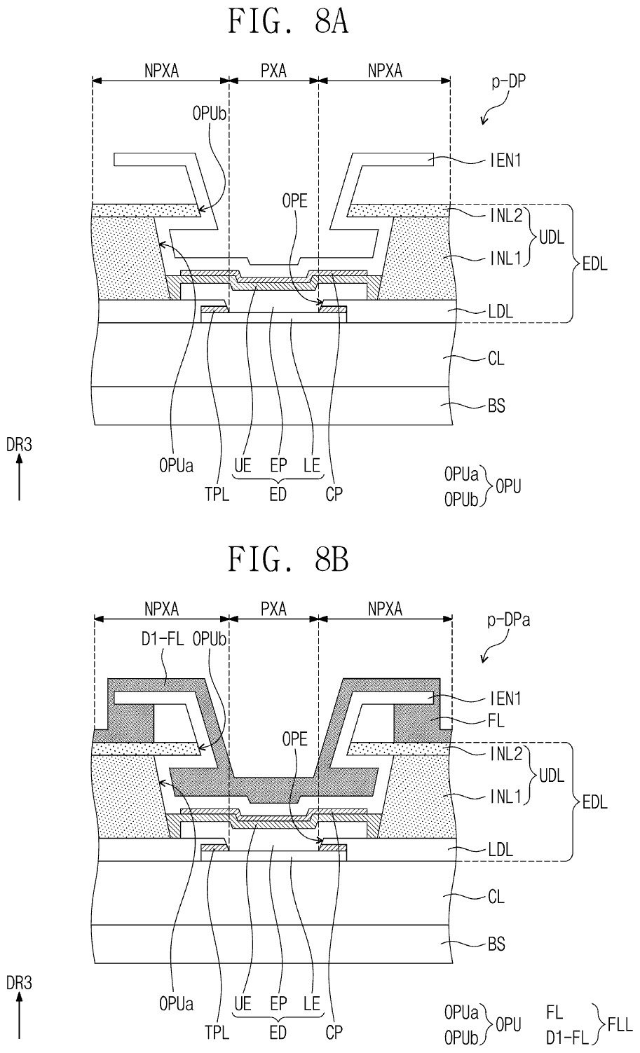

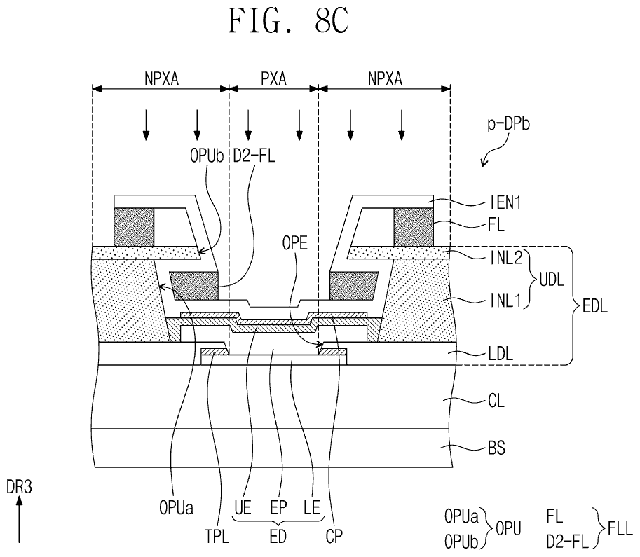

FIG. 7 is a flowchart of a method of providing (or manufacturing) a display panel DP according to an embodiment of the present disclosure. FIGS. 8A to 8C are cross-sectional views showing structures provided in the method of providing the display panel DP according to an embodiment of the present disclosure, respectively.

Referring to FIG. 7, the method of the present disclosure may include providing a preliminary display panel p-DP (S100) and forming (or providing) a filler layer FLL (see FIG. 8B).

FIG. 8A schematically shows the providing of the preliminary display panel p-DP (S100). Referring to FIG. 8A, the preliminary display panel p-DP may include the first electrode LE, the lower pixel defining layer LDL which covers a portion of the first electrode LE and defines the light-emitting opening OPE as a lower opening which corresponds to a planar area of the exposed potion of the first electrode LE, the upper pixel defining layer UDL which defines the upper opening OPU and is disposed on the lower pixel defining layer LDL, the light-emitting pattern EP disposed inside the upper opening OPU on the first electrode LE, the second electrode UE disposed on the light-emitting pattern EP, and the first encapsulation inorganic film IEN1 disposed on the second electrode UE. The upper opening OPU may be defined by a lower sub-opening OPUa and an upper sub-opening OPUb. Here, the light-emitting opening OPE, the lower sub-opening OPUa and the upper sub-opening OPUb may be first, second and third sub-openings which together define a pixel opening in a pixel defining layer LDL and UDL. In an embodiment, for example, the pixel defining layer includes the lower pixel defining layer LDL including a first sub-opening of the light-emitting opening OPE defined therein, the first inorganic layer INL1 on the lower pixel defining layer LDL and including a side surface defining a second sub-opening of the light-emitting opening OPE which corresponds to the first sub-opening, a second inorganic layer INL2 on the first inorganic layer INL1, and including a side surface defining a third sub-opening of the light-emitting opening OPE which corresponds to the second sub-opening, and the second inorganic layer INL2 protruding further than the side surface of the first inorganic layer INL1 in a direction toward the light-emitting opening OPE to define a tip of the pixel defining layer LDL and UDL.

The first encapsulation inorganic film IEN1 may include the first portion P1 which is disposed within the upper opening OPU and covers the second electrode UE and the side surface of the upper pixel defining layer UDL, the second portion P2 extending in a direction from the first electrode LE toward the second electrode UE (e.g., a thickness direction of the preliminary display panel p-DP) from an end of the first portion P1, and the third portion P3 extending in a direction away from the center of the light-emitting pattern EP from an end of the second portion P2. The second portion P2 is not limited to the case of extending exactly in the thickness direction. For example, it is shown in FIGS. 8A to 8C that the second portion P2 extends at a predetermined angle from the thickness direction. The content described above in FIGS. 3 to 6B may be equally applied to the base layer BS, the circuit layer CL, the light-emitting element layer EDL, and the first encapsulation inorganic film IEN1 within the preliminary display panel p-DP.

FIG. 8B schematically shows the forming of the filler layer FLL (S200) relative to the preliminary display panel p-DP. Herein, the filler layer FLL may include both the filler FL and the dummy fillers D1-FL and D2-FL described above. The filler layer FLL may be a filler material layer including both the filler FL and the dummy fillers D1-FL and D2-FL as respective patterns of the filler material layer (e.g., in a same layer as each other).

Referring to FIG. 8B, a filler layer material of the filler layer FLL may be formed on the first encapsulation inorganic film IEN1. Referring to FIG. 8B, portions of the filler layer FLL may be both under and above the first encapsulation inorganic film IEN1 to provide the filler FL and the dummy filler and D1-FL.

A first preliminary display panel p-DPa may be manufactured (or provided) by forming the filler layer material layer of the filler layer FLL on the first encapsulation inorganic film IEN1. In an embodiment, the first preliminary display panel p-DPa may include the filler layer material layer continuously on an entirety of the first encapsulation inorganic film IEN1 to provide the filler layer FLL. Thereafter, the display panel DP in FIG. 6A may be manufactured by forming the encapsulation organic film OEN (see FIG. 6A) and the second encapsulation inorganic film IEN2 (see FIG. 6A) on the filler layer FLL.

The filler layer FLL may be formed by depositing hexamethyldisiloxane on the first encapsulation inorganic film IEN1. Hexamethyldisiloxane may be deposited via a chemical vapor deposition (CVD) process. Hexamethyldisiloxane may have the excellent reflow properties. Additionally, hexamethyldisiloxane may have the properties which prevent the penetration of moisture and oxygen. In the case of the hexamethyldisiloxane deposition process, a high temperature process such as forming and curing an organic layer is not necessary, so that the light-emitting element ED, such as the already formed organic layer, may be prevented from being damaged by a high temperature. In addition, processability may be excellent because no separate heat treatment such as hardening is required.

The filler layer FLL may be formed by sealing the space between the upper pixel defining layer UDL and the third portion P3 of the first encapsulation inorganic film IEN1. Here, the filler layer FLL extends across an inlet of the gap between the upper pixel defining layer UDL and the third portion P3. The space between the upper pixel defining layer UDL and the third portion P3 of the first encapsulation inorganic film IEN1 may be completely filled or only partially filled, but in both cases, the filler layer FLL extends across the inlet of the gap to seal the space.

As the space between the upper pixel defining layer UDL and the third portion P3 of the first encapsulation inorganic film IEN1 is sealed at the inlet, in the process for forming one type of a pixel area PXA and then forming another type of the pixel area, the moisture penetration and/or the physicochemical damage to a material exposed via the space between the upper pixel defining layer UDL and the third portion P3 of the first encapsulation inorganic film IEN1 may be prevented.

Hexamethyldisiloxane may include silicon atoms, oxygen atoms, and carbon atoms. That is, hexamethyldisiloxane may have the SiOₓC_{y} composition. The ratio of oxygen atoms to silicon atoms in hexamethyldisiloxane may be equal to or greater than about 1.5 and equal to or smaller than about 2.5. The ratio of carbon atoms to silicon atoms in hexamethyldisiloxane may be equal to or smaller than about 0.6. In the above ranges, hexamethyldisiloxane may have the properties similar to those of silicon oxide (SiO₂) and therefore may have the transparent properties. Therefore, even when the filler layer FLL is formed to overlap the pixel area PXA along the thickness direction, light-emitting characteristics may not be affected. Full deposition is possible, and thus, no additional mask is needed, so that the processability may be excellent.

The method of providing the display panel DP of the present disclosure may further include etching the filler layer FLL, such as in an anisotropic manner. FIG. 8C schematically shows the etching of the filler layer FLL in the first preliminary display panel p-DPa, in the anisotropic manner. Here, the method further includes anisotropically etching the filler material layer to provide a filler FL in the gap and a dummy filler D2-FL which is in the light-emitting opening OPE and disconnected from the filler FL.

Referring to FIG. 8C, portions of the filler layer FLL may remain both under and above the first encapsulation inorganic film IEN1 to provide the filler FL and the dummy filler D2-FL, respectively. Here, the patterns of the filler FL and the dummy filler D2-FL are in a same layer as each other as being respective portions of a same material layer (e.g., the filler layer FLL in FIG. 8B). The filler FL and the dummy filler D2-FL are disconnected from each other.

A second preliminary display panel p-DPb may be manufactured by etching the filler layer FLL in the first preliminary display panel p-DPa in the anisotropic manner. Thereafter, the display panel DP in FIG. 6B may be manufactured by forming the encapsulation organic film OEN (see FIG. 6B) and the second encapsulation inorganic film IEN2 (see FIG. 6B) on the filler layer FLL which is patterned (e.g., an etched filler layer).

In the process for forming one type of the pixel area PXA and then forming another type of the pixel area, the etching process may be required. Even when the anisotropic etching process is progressed, the space between the upper pixel defining layer UDL and the third portion P3 of the first encapsulation inorganic film IEN1 may remain sealed at least at the inlet thereof, by a portion of the filler layer FLL. Therefore, even in this case, the moisture penetration and/or the physicochemical damage during the process may be prevented, as described above in FIG. 8B.

Although the description has been made with reference to embodiments of the present disclosure, those skilled in the art or have ordinary knowledge in the relevant technical field will understand that the present disclosure may be modified and changed in various ways without departing from the ideas and the technical scope of the present disclosure described in the claims to be described later.

Therefore, the technical scope of the present disclosure should not be limited to the content described in the detailed description of the present document, but should be determined by the claims.

According to the above description, the display panel DP that may implement the high resolution and have the improved reliability may be provided.

In addition, the method for manufacturing (or providing) the display panel DP with the improved processability and the improved reliability by reducing the moisture penetration and the physical and chemical damage during the process may be provided. In embodiments, light-emitting structures may be provided in succession. In forming a subsequent light-emitting structure (e.g., the another type of the pixel area) in a subsequent pixel opening, exposure of a material of a previous light-emitting structure (e.g., the one type of the pixel area PXA) at a previous gap under a previous inorganic encapsulation layer adjacent to a previous pixel opening is blocked by a filler layer FLL which seals an inlet of the previous gap.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display panel comprising:
a circuit layer;
a light-emitting element layer which is on and connected to the circuit layer, the light-emitting layer including:
a first electrode;
a pixel defining layer including a light-emitting opening defined therein which exposes a portion of the first electrode to outside the pixel defining layer, and a side surface which defines the light-emitting opening; and
within the light-emitting opening, a light-emitting pattern on the first electrode and a second electrode which is on the light-emitting pattern;
an encapsulation layer covering the light-emitting element layer, the encapsulation layer comprising a first encapsulation inorganic film, wherein the first encapsulation inorganic film includes:
a first portion within the light-emitting opening, the first portion covering the second electrode and the side surface of the pixel defining layer,
a second portion extending from the first portion along a thickness direction of the display panel, and
a third portion extending from the second portion in a direction away from the light-emitting opening; and
a filler comprising hexamethyldisiloxane, the filler being between the pixel defining layer and the third portion of the first encapsulation inorganic film.

2. The display panel of claim 1, wherein the filler comprises silicon atoms and oxygen atoms, a ratio of the oxygen atoms to the silicon atoms being equal to or greater than about 1.5 and equal to or smaller than about 2.5.

3. The display panel of claim 1, wherein the filler comprises silicon atoms and carbon atoms, a ratio of the carbon atoms to the silicon atoms being equal to or smaller than about 0.6.

4. The display panel of claim 1, wherein a transmittance in a visible light band of the filler is equal to or greater than about 95%.

5. The display panel of claim 1, wherein
the third portion of the first encapsulation inorganic film extends further than the pixel defining layer along the thickness direction to define a gap between the third portion of the first encapsulation inorganic film and the pixel defining layer along the thickness direction, and
the filler is in the gap.

6. The display panel of claim 1, wherein
the third portion of the first encapsulation inorganic film extends further than the pixel defining layer along the thickness direction to define a gap between the third portion and the pixel defining layer along the thickness direction, and
the filler contacts each of the third portion of the first encapsulation inorganic film and the pixel defining layer to seal the gap.

7. The display panel of claim 1, further comprising a filler material layer including:
a dummy filler covering each of the first portion of the first encapsulation inorganic film, a side surface of the second portion which faces the light-emitting pattern, and a top surface of the third portion, and
the filler.

8. The display panel of claim 7, wherein the filler and the dummy filler are connected to each other.

9. The display panel of claim 1, further comprising a filler material layer including:
a dummy filler spaced apart from the pixel defining layer with the first portion of the first encapsulation inorganic film between, and
the filler.

10. The display panel of claim 9, wherein the filler and the dummy filler are disconnected from each other.

11. The display panel of claim 1, wherein a side surface of the second portion of the first encapsulation inorganic film faces the filler and is spaced apart from the filler to define a gap between the second portion and the filler.

12. The display panel of claim 1, wherein a side surface of the second portion of the first encapsulation inorganic film faces the filler and contacts the filler.

13. The display panel of claim 1, wherein the pixel defining layer includes:
a lower pixel defining layer including a first sub-opening of the light-emitting opening defined therein;
a first inorganic layer on the lower pixel defining layer, the first inorganic layer including a side surface defining a second sub-opening of the light-emitting opening which corresponds to the first sub-opening;
a second inorganic layer on the first inorganic layer, the second inorganic layer including a side surface defining a third sub-opening of the light-emitting opening which corresponds to the second sub-opening; and
the second inorganic layer protruding further than the side surface of the first inorganic layer in a direction toward the light-emitting opening to define a tip of the pixel defining layer.

14. The display panel of claim 1, wherein the encapsulation layer further comprises:
an encapsulation organic film which is on the first encapsulation inorganic film and planarizes the first encapsulation inorganic film; and
a second encapsulation inorganic film on the encapsulation organic film.

15. A method of providing a display panel, the method comprising:
providing a preliminary display panel including:
a first electrode of a light-emitting element,
a pixel defining layer including a light-emitting opening defined therein which exposes a portion of the first electrode to outside the pixel defining layer, and a side surface which defines the light-emitting opening,
within the light-emitting opening, a light-emitting pattern and a second electrode of the light-emitting element, and
a first encapsulation inorganic film of an encapsulation layer which is on the second electrode, wherein the first encapsulation inorganic film includes:
a first portion within the light-emitting opening, the first portion covering the second electrode and the side surface of the pixel defining layer,
a second portion extending from the first portion along a thickness direction of the preliminary display panel, and
a third portion extending from the second portion in a direction away from the light-emitting opening; and
providing a filler material layer by providing hexamethyldisiloxane on the first encapsulation inorganic film of the preliminary display panel.

16. The method of claim 15, wherein
within the preliminary display panel, the third portion of the first encapsulation inorganic film extends further than the pixel defining layer along the thickness direction to define a gap between the third portion and the pixel defining layer along the thickness direction, and
the filler material layer is provided on an entirety of the preliminary display panel and seals the gap between the pixel defining layer and the third portion of the first encapsulation inorganic film.

17. The method of claim 15, further comprising:
anisotropically etching the filler material layer to provide a filler in the gap and a dummy filler which is in the light-emitting opening and disconnected from the filler.

18. The method of claim 15, wherein
the hexamethyldisiloxane includes silicon atoms and oxygen atoms, and
a ratio of the oxygen atoms to the silicon atoms is equal to or greater than about 1.5 and equal to or smaller than about 2.5.

19. The method of claim 15, wherein
the hexamethyldisiloxane includes silicon atoms and carbon atoms, and
a ratio of the carbon atoms to the silicon atoms is equal to or smaller than about 0.6.

20. The method of claim 15, wherein the providing of the filler material layer includes depositing the hexamethyldisiloxane via chemical vapor deposition.
